(19) United States
(12) Patent Application Publication
(10) Pub. No.: US 2021/0384066 A1
(43) Pub. Date: Dec. 9, 2021

(54) METHOD FOR PREPARING TRENCH ISOLATION STRUCTURE AND METHOD FOR PREPARING SEMICONDUCTOR DEVICE

(71) Applicant: CHANGXIN MEMORY TECHNOLOGIES, INC., Hefei City (CN)

(72) Inventors: ChenMing XU, Hefei (CN); BEONSEOK CHA, Hefei (CN); WenJing GUAN, Hefei (CN)

(73) Assignee: CHANGXIN MEMORY TECHNOLOGIES, INC., Hefei City (CN)

(21) Appl. No.: 17/406,970

(22) Filed: Aug. 19, 2021

Related U.S. Application Data
(63) Continuation of application No. PCT/CN2021/081784, filed on Mar. 19, 2021.

(30) Foreign Application Priority Data
Apr. 9, 2020 (CN) 202010272967.0

(51) Int. Cl. H01L 21/762

(52) U.S. Cl. CPC H01L 21/76229

(57) ABSTRACT

The present application relates to a method for preparing a trench isolation structure and a method for preparing a semiconductor device. The method for preparing a trench isolation structure comprises opening a trench on a substrate, and filling a first dielectric layer of a preset thickness at the bottom of the trench; forming a compensation film on the sidewalls of the trench above the first dielectric layer; filling a second dielectric layer into the trench to form the trench isolation structure, with the compensation film be completely consumed after filling the second dielectric layer.

### CROSS-REFERENCE OF RELATED APPLICATIONS

This application is a continuation application of International Patent Application No. PCT/CN2021/081784, filed on Mar. 19, 2021, which claims priority to Chinese Patent Application No. 202010272967.0, filed on Apr. 9, 2020. The above-referenced applications are incorporated herein by reference in their entirety.

### TECHNICAL FIELD

The application relates to the field of semiconductors, in particular to a method for preparing a trench isolation structure and a method for preparing a semiconductor device.

### BACKGROUND

Semiconductor devices need to form trench isolation structures to realize the isolation of adjacent active regions. In the specific process, after a trench is opened on a substrate, it is usually subject to such processes as cleaning, thermal oxidation, atomic layer deposition (ALD) and the like. In order to reduce the loss in size of the active regions during the above processes, polysilicon thin film compensation technology is generally introduced, that is, after the trench is opened, a layer of polysilicon thin film is formed on the inner wall of the trench, and the introduced polysilicon thin film will be consumed during the above processes of cleaning, thermal oxidation, atomic layer deposition (ALD) and the like, thereby reducing the loss in size of the active regions.

However, in the practical application of polysilicon thin film compensation technology, when the ratio of depth to width of the trench is relatively high or the bottom of the trench is relatively narrow, there is usually the polysilicon thin film remaining at the bottom of the trench without being consumed, leading to a smaller actual depth of the trench isolation structure and a weakened isolation effect.

### SUMMARY

According to various embodiments of the application, a method for preparing a trench isolation structure and a method for preparing a semiconductor device are provided.

A method for preparing a trench isolation structure comprises:

opening a trench on a substrate, and filling a first dielectric layer of a preset thickness at the bottom of the trench;

forming a compensation film on the sidewalls of the trench above the first dielectric layer; and

filling a second dielectric layer into the trench to form the trench isolation structure, with the compensation film be completely consumed after filling the second dielectric layer.

In one of the embodiments, said filling the first dielectric layer with a preset depth at the bottom of the trench comprises:

depositing a first dielectric material to fill up the trench;

etching back the first dielectric material, and reserving the first dielectric material at the bottom of the trench, wherein the reserved first dielectric material forms the first dielectric layer.

In one of the embodiments, the depth of the first dielectric material etched back within the trench ranges from 70 nm to 300 nm.

In one of the embodiments, the first dielectric layer is spin-coated carbon or photoresist.

In one of the embodiments, said forming the compensation film on the sidewalls of the trench above the first dielectric layer comprises:

depositing a compensation material to cover the sidewalls of the trench, the upper surface of the first dielectric layer and the upper surface of the substrate;

etching back the compensation material to remove the compensation material located on the upper surface of the first dielectric layer and the upper surface of the substrate, reserving the compensation material located at the sidewalls of the trench, wherein the reserved compensation material forms the compensation film.

In one of the embodiments, said forming the compensation film on the sidewalls of the trench above the first dielectric layer comprises:

growing an epitaxial layer on the sidewalls of the trench by epitaxial growth to be the compensation film.

In one of the embodiments, the compensation film is a polysilicon layer.

In one of the embodiments, the thickness of the polysilicon layer ranges from 5 Å to 50 Å.

In one of the embodiments, after forming the compensation film on the sidewalls of the trench above the first dielectric layer and before filling the second dielectric layer into the trench to form the trench isolation structure, the method further comprises:

removing the first dielectric layer.

In one of the embodiments, said filling the second dielectric layer into the trench to form the trench isolation structure comprises:

Filling up the second dielectric layer in the trench by a chemical vapor deposition process or an atomic layer deposition process to form the trench isolation structure.

In one of the embodiments, the second dielectric layer comprises one or more of oxide, nitride and oxynitride.

A method for preparing a semiconductor device comprises:

preparing a trench isolation structure on a substrate by the method for preparing a trench isolation structure described above to define an active region;

preparing a transistor structure in the active region to form the semiconductor device.

In one of the embodiments, the semiconductor device is a dynamic random access memory, and a gate of the transistor is prepared within the substrate to form a buried word line.

With the method for preparing a trench isolation structure described above, the first dielectric layer of a preset thickness is filled at the bottom of the trench first, and then a layer of compensation film is formed on the sidewalls of the trench above the first dielectric layer, so that the compensation film is not formed at the bottom of the trench since the first dielectric layer is filled at the bottom of the trench. When the second dielectric layer is filled within the trench to form the trench isolation structure, the compensation film will be consumed in the processes of cleaning and deposition. In this application, firstly, thin film compensation technology is introduced, which can reduce the loss of the active region in the processes of cleaning, thermal oxidation and the like; at the same time, no compensation film is formed at the bottom of the trench, which can avoid the phenomenon that the compensation film in the narrow area at the bottom of the trench is difficult to be consumed and remains, that is, with the method for preparing a trench isolation structure described above, the loss in size of the active region can be reduced, and the isolation effect of the trench isolation structure can be ensured as well.

### BRIEF DESCRIPTION OF DRAWINGS

The above and other objects, features and advantages of the present application will become more apparent from the more specific description of the preferred embodiments of the present application shown in the accompanying drawings. In all the drawings, the same reference numerals indicate the same parts, and the drawings are not deliberately drawn in equal scales according to actual size, with emphasis being put on showing the main idea of the application.

FIG. 1a and FIG. 1b are structural schematic diagrams corresponding to relevant steps of a preparation method for forming a trench isolation structure in the conventional art;

FIG. 2 is a step flow chart of a method for preparing a trench isolation structure according to an embodiment;

FIG. 3a to FIG. 3f are structural schematic diagrams corresponding to relevant steps of a method for preparing a trench isolation structure according to an embodiment;

FIG. 4 is a top view of a trench isolation structure according to an embodiment after defining an active region;

FIG. 5 is a structural schematic diagram of a dynamic random access memory according to an embodiment.

### DESCRIPTION OF EMBODIMENTS

In order to make the above objects, features and advantages of this application more obvious and understandable, the specific implementations of this application will be described in detail with reference to the accompanying drawings. In the following description, numerous specific details are set forth in order to provide a thorough understanding of the application. However, the application can be implemented in many other ways than those described herein, those skilled in the art can make similar improvements without departing from the content of this application, so this application is not limited by the specific implementations disclosed below.

Unless otherwise defined, all technical and scientific terms used herein have the same meanings as those commonly understood by those skilled in the technical field of this application. Terms used herein in the specification of this application are for the purpose of describing specific embodiments only and are not intended to limit this application. As used herein, the term “and/or” includes any and all combinations of one or more related listed items.

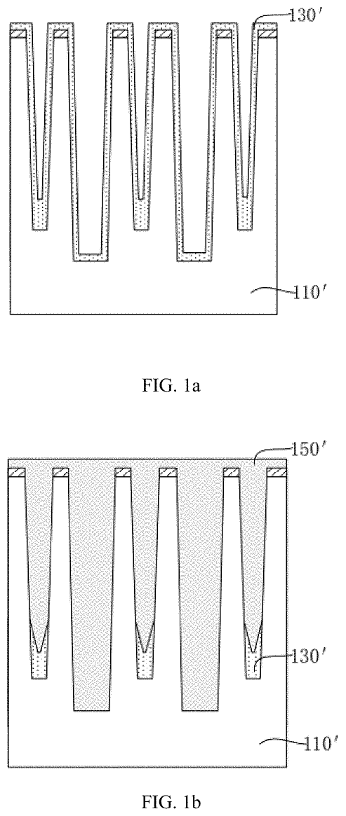

In conventional technology, as shown in FIG. 1a and FIG. 1b, a layer of polysilicon thin film 130′ is formed on the inner wall of a trench and the upper surface of a substrate 110′ by using polysilicon thin film compensation technology after the trench is opened on the substrate 110′. Then, a dielectric layer 150′ is filled up within the trench by employing chemical vapor deposition (CVD) process or atomic deposition (ALD) process to form a trench isolation structure. Before filling the dielectric layer 150′, there may also be a cleaning process. In this process, the polysilicon thin film 130′ will be consumed in the processes of cleaning, thermal oxidation, atomic layer deposition (ALD) and the like, reducing the loss of an active region. However, as shown in FIG. 1b, the polysilicon thin film 130′ still remains in the narrow area at the bottom of the trench without being consumed, resulting to a shallower depth of the trench isolation structure and weakening the isolation effect.

The present application relates to a method for preparing a trench isolation structure, which comprises at least the following steps:

a trench is opened on a substrate, and a first dielectric layer of a preset thickness is filled at the bottom of the trench;

a compensation film is formed on the sidewalls of the trench above the first dielectric layer;

a second dielectric layer is filled within the trench to form the trench isolation structure, and the compensation film is completely consumed in the process of filling the second dielectric layer.

It should be noted that, the preset thickness of the first dielectric layer can be set according to the thickness of the compensation film. For example, the filling height of the residual compensation film at the bottom of the trench in the conventional technology can be obtained first, and the preset thickness of the first dielectric layer is greater than or equals to the filling height of the residual compensation film in the conventional technology. No compensation film is formed in the narrow area at the bottom of the trench, thus avoiding the problem of remaining the compensation film in the narrow area at the bottom of the trench.

In addition, by the compensation film being completely consumed after filling the second dielectric layer, it means that the compensation film is consumed in the cleaning process after forming the compensation film and in the deposition process of the second dielectric layer, which may be by physically removing or transforming into dielectric structure by chemical reaction, and the compensation film is completely consumed after completing the filling of the second dielectric layer. Therefore, the thickness design of the compensation film is related to the specific process, and it is necessary to ensure that the compensation film will be completely consumed in the subsequent cleaning and deposition process.

With the method for preparing a trench isolation structure described above, the first dielectric layer of a preset thickness is filled at the bottom of the trench first, and then a layer of compensation film is formed on the sidewalls of the trench above the first dielectric layer, so that the compensation film is not formed at the bottom of the trench since the first dielectric layer is filled at the bottom of the trench. When the second dielectric layer is filled within the trench to form the trench isolation structure, the compensation film will be consumed in the processes of cleaning and deposition. In this application, firstly, thin film compensation technology is introduced, which can reduce the loss of the active region in the processes of cleaning, thermal oxidation and the like; at the same time, no compensation film is formed at the bottom of the trench, which can avoid the phenomenon that the compensation film in the narrow area at the bottom of the trench is difficult to be consumed and remains, that is, with the method for preparing a trench isolation structure described above, the loss in size of the active region can be reduced, and the isolation effect of the trench isolation structure can be ensured as well.

In the following, the method for preparing a trench isolation structure is introduced in detail with a specific embodiment.

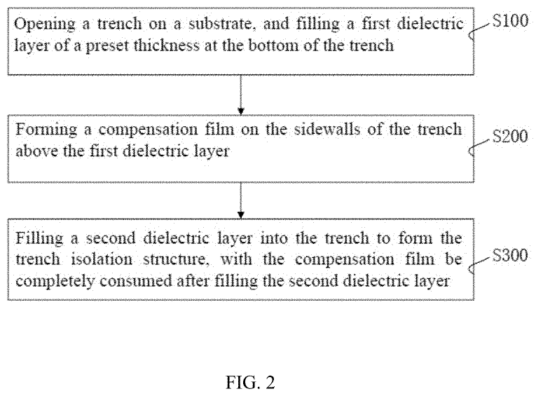

As shown in FIG. 2, the method for preparing a trench isolation structure in the application comprises the following steps:

step S100: A trench is opened on a substrate, and a first dielectric layer of a preset thickness is filled at the bottom of the trench;

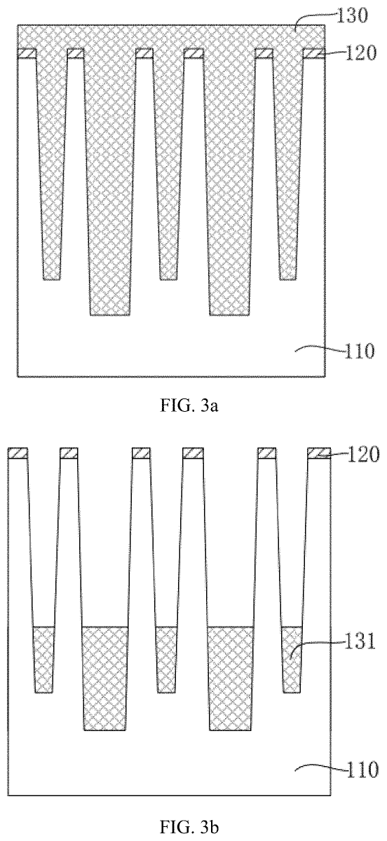

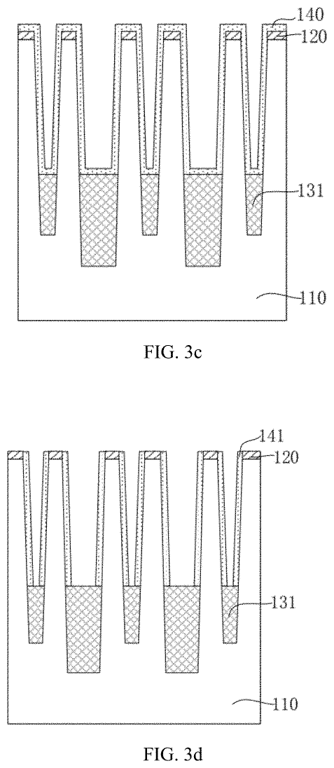

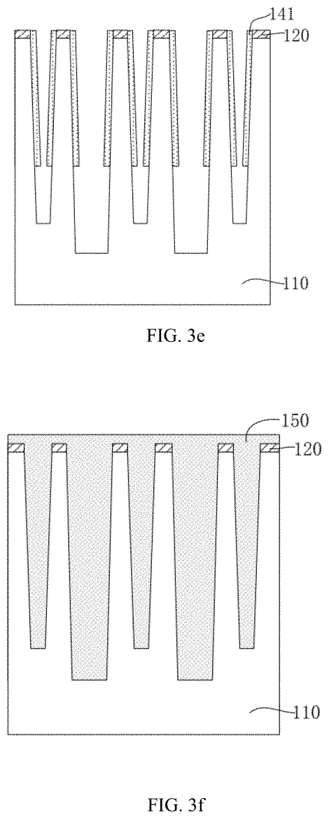

as shown in FIG. 3b, a trench is opened on the substrate 110, and a first dielectric layer 131 of a preset thickness is filled at the bottom of the trench;

here, the substrate 110 can be one of silicon wafer, germanium wafer, silicon-on-insulator (SOI) wafer, germanium-on-insulator (GOI) wafer, Si—Ge wafer and substrate formed with an epitaxial layer.

Specifically, in opening the trench on the substrate 110, a mask layer 120 can be formed on the substrate 110 first, and an etching pattern is defined by the mask layer 120, and then the trench is etched in the substrate 110 through etching process. The mask layer 120 is a hard mask, and silicon nitride or silicon oxide can be selected specifically. Specifically, self-aligned multiple exposure process (SAQP) can be utilized to form the above trench, with which a structure of a small size can be obtained. Generally, the trench is in an inverted trapezoid shape with wide top and narrow bottom. Here, the opening width of the trench can be set as desired, and the opening width of the trenches can be the same or different. When the opening width of the trenches is different, the larger the opening width of the trench is, the deeper the etching depth is, that is, the etching depth of the trench with wider opening width is deeper than that of the trench with narrower opening width. At this time, we only need to ensure that the preset thickness of the first dielectric layer 131 filled in the shallowest trench is greater than the filling height of the residual compensation film in the conventional technology.

In a specific embodiment, the first dielectric layer 131 of the preset thickness can be filled at the bottom of the trench by the following sub-steps:

step S110: a first dielectric material is deposited to fill up the trench;

step S120: the first dielectric material is etched back to a preset depth, the first dielectric material at the bottom of the trench is reserved, and the reserved first dielectric material forms the first dielectric layer.

In connection with what is shown in FIG. 3a and FIG. 3b, firstly, the first dielectric material 130 is deposited to fill up the trench. Specifically, the first dielectric material 130 fills up the trench and overflows the trench to a certain height to ensure that the trench is filled up with the first dielectric material 130. Then, the first dielectric material 130 is etched back to a preset depth, and the first dielectric material 130 with the preset thickness at the bottom of the trench is reserved, the reserved first dielectric material 130 forms the first dielectric layer 131 of the preset thickness. In an embodiment, before the first dielectric material 130 is etched back, the surface of the first dielectric material 130 can also be planarized by a chemical mechanical grinding process, and then the first dielectric material 130 is etched to a preset depth. The etching process used in the back etching can be dry etching, in particular plasma etching. Specifically, the depth of the first dielectric material 130 etched back in the trench ranges from 70 nm to 300 nm.

Step S200: a compensation film is formed on the sidewalls of the trench above the first dielectric layer.

As shown in FIG. 3d, a compensation film 141 is formed on the sidewalls of the trench above the first dielectric layer 131, which is thin and adheres to the sidewalls of the trench and does not fill up the trench.

Here, the compensation film 141 can be formed in a variety of ways.

For example, in a specific embodiment, the compensation film 141 can be formed on the sidewalls of the trench above the first dielectric layer 131 by the following sub-steps:

step S211: a compensation material is deposited to cover the sidewalls of the trench, the upper surface of the first dielectric layer and the upper surface of the substrate;

step S212: the compensation material is etched back to remove the compensation material on the upper surface of the first dielectric layer and the upper surface of the substrate, the compensation material at the sidewalls of the trench is reserved, and the reserved compensation material forms the compensation film.

In connection with what is shown in FIG. 3c and FIG. 3d, firstly, a layer of compensation material 140 is deposited by a deposition process. The compensation material 140 covers the sidewalls of the trench, the upper surface of the first dielectric layer 131 and the upper surface of the substrate 110. When the mask layer 120 on the substrate 110 is not removed, the compensation material 140 covers the upper surface of the substrate 110, actually overlying the mask layer 120. After deposition of the compensation material 140, the compensation material 140 is then etched back, and the compensation material 140 is thinned along the direction perpendicular to the upper surface of the substrate 110 to remove the compensation material 140 on the upper surface of the first dielectric layer 131 and the upper surface of the substrate 110, the compensation material 140 at the sidewalls of the trench is reserved, and the reserved compensation material 140 forms the compensation film 141. Specifically, the deposition process can be chemical vapor deposition process or atomic layer deposition process.

For example, in another embodiment, the compensation film 141 can also be formed on the trench sidewalls above the first dielectric layer 131 in such a way of epitaxial growth to grow an epitaxial layer on the sidewalls of the trench to be the compensation film 141. At this time, since the trench has the first dielectric layer 131, the deposited upper surface has the mask layer 120, and epitaxial growth would not occur on the first dielectric layer 131 and the mask layer 120, therefore, the epitaxial layer is only grown on the exposed sidewalls of the trench, and the epitaxial layer grown is directly served as the compensation film 141.

Here, the above compensation film 141 may be a thin film consumed in a cleaning or deposition process. The compensation film 141 may have the same material as the substrate 110. Specifically, the compensation film 141 can be semiconductor materials such as silicon, germanium and the like. For example, the compensation film 141 is a polysilicon layer, and the thickness of the polysilicon layer ranges from 5 Å to 50 Å.

In an embodiment, after the compensation film 141 is formed on the sidewalls of the trench above the first dielectric layer 131, the method further comprises the step of removing the first dielectric layer 131.

As shown in FIG. 3e, the first dielectric layer 131 at the bottom of the trench is removed. At this time, only the compensation film 141 formed on the sidewalls of the trench is remained in the trench, and the compensation film 141 does not extend to the bottom of the trench.

S300: a second dielectric layer is filled within the trench to form the trench isolation structure, with the compensation film be completely consumed after filling the second dielectric layer.

As shown in FIG. 3f, a second dielectric layer 150 is filled within the trench to form the trench isolation on the substrate 110, at this time, the compensation film 141 is completely consumed after filling the second dielectric layer 150. Specifically, in filling the second dielectric layer 150 within the trench, the second dielectric layer 150 may be filled up within the trench by any one of chemical vapor deposition (CVD) process, physical vapor deposition (PVD) process, atomic layer deposition (ALD) process or spin-coating insulating dielectric layer (SOD) process, and of course, other suitable processes may also be used. Among them, chemical vapor deposition process may specifically include plasma enhanced chemical vapor deposition (PECVD), high density plasma chemical vapor deposition (HDPCVD), flame chemical vapor deposition (FCVP), atmospheric pressure chemical vapor deposition (APCVD) or low pressure chemical vapor deposition (LPACVD). Specifically, the second dielectric layer 150 includes one or more materials of low-k dielectrics, for example, the second dielectric layer 150 may include oxide, nitride or oxynitride, or a composite structure layer of oxide and nitride such as silicon oxide-silicon nitride-silicon oxide (ONO structure).

It should be noted that, the compensation film 141 is consumed, which may be by being thinned by physically removing in the cleaning process, or may be by transforming into oxide by thermally oxidizing to fill within the trench as a dielectric structure.

In an embodiment, if the first dielectric layer 131 is removed before filling the second dielectric layer 150, the second dielectric layer 150 fills the entire trench. In this embodiment, if the first dielectric layer 131 is to be removed, then materials with high selectivity which can be easily removed are selected for the first dielectric layer 131, such as photoresist materials such as spin-on carbon (SOC), amorphous carbon layer (ACL), photoresist and the like.

In other embodiments, it is also possible that the first dielectric layer 131 is not removed, the first dielectric layer 131 is filled at the bottom of the trench, and the second dielectric layer 150 is filled at the top of the trench, that is, both the first dielectric layer 131 and the second dielectric layer 150 are filled in the trench. At this time, the first dielectric layer 131 and the second dielectric layer 150 have the same properties, and are made of one or more materials of low-k dielectrics, for example, the second dielectric layer 150 may be an oxide or nitride, or a composite structure layer of oxide and nitride.

With the method for preparing a trench isolation structure described above, the first dielectric layer 131 of the preset thickness is filled at the bottom of the trench first, and then a layer of compensation film 141 is formed on the sidewalls of the trench above the first dielectric layer 131, so that the compensation film 141 is not formed at the bottom of the trench since the first dielectric layer 131 is filled at the bottom of the trench. When the second dielectric layer 150 is filled within the trench to form the trench isolation structure, the compensation film 141 will be consumed in the processes of cleaning and deposition. In this application, firstly, thin film compensation technology is introduced, which can reduce the loss of the active region 111 in the processes of cleaning, thermal oxidation and the like; at the same time, no compensation film 141 is formed at the bottom of the trench, which can avoid the phenomenon that the compensation film 141 in the narrow area at the bottom of the trench is difficult to be consumed and remains, that is, with the method for preparing a trench isolation structure described above, the loss in size of the active region 111 can be reduced, and the isolation effect of the trench isolation structure can be ensured as well.

The application also relates to a method for preparing a semiconductor device, which comprises:

preparing a trench isolation structure on a substrate by the method for preparing a trench isolation structure described above to define an active region;

preparing a transistor structure in the active region to form the semiconductor device.

In connection with what is shown in FIG. 3f and FIG. 4, wherein FIG. 4 is a top view of the active region 111 defined by the trench isolation structure on the substrate 110, and FIG. 3f is a side sectional view along the section line AN in FIG. 4. The trench isolation structure is prepared on the substrate 110 by the method for preparing a trench isolation structure in any one of the above embodiments, and the active region 111 is defined by the trench isolation structure, that is, the area of the substrate 110 forming the trench isolation structure is the active region 111. Transistors are formed in the active region 111 by processes of doping and the like, thus preparing the semiconductor devices.

By introducing an improved method for preparing a trench isolation structure to prepare a trench isolation structure, the method for preparing a semiconductor device described above can not only reduce the loss in size of the active region 111, but also ensure the isolation effect, thus improving the stability of the semiconductor devices.

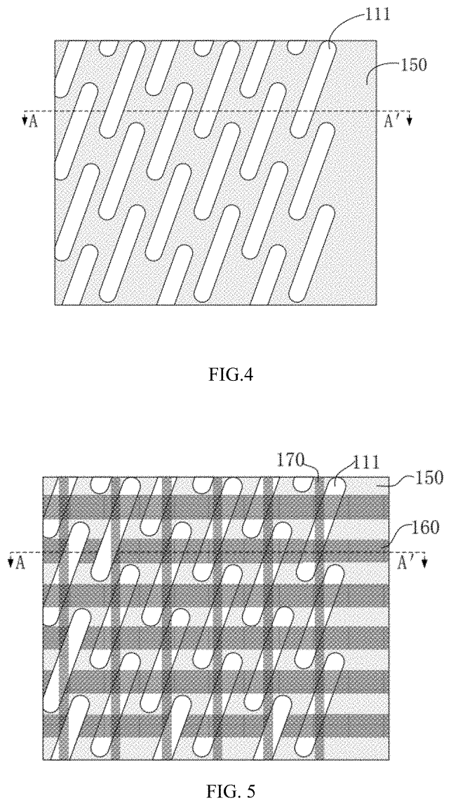

In a specific embodiment, the semiconductor device described above is a dynamic random access memory (DRAM). In connection with what is shown in FIG. 4 and FIG. 5, agate of the transistor is prepared within the substrate 110 to form a buried word line 160 of DRAM. A drain of the transistor is connected with a bit line 170 of the DRAM, and the bit line 170 interleaves with the word line 160 vertically and horizontally, and a source of the transistor is connected with a storage capacitor (not shown). In the present embodiment, DRAM forms the buried word line 160, the depth of which is limited by the depth of the trench isolation structure. Since the trench isolation structure formed in the application can avoid the reservation of the compensation film 141 at the bottom of the trench, that is, the depth of the formed trench isolation structure is not affected by the compensation film 141, therefore, when DRAM is prepared by the above method, the effect of the reservation of the compensation film 141 on the depth of the buried word line 160 can be improved.

Each technical feature of the above-mentioned embodiments can be arbitrarily combined. In order to make the description concise, all possible combinations of each technical feature in the above-mentioned embodiments are not described. However, the combinations of these technical features shall be considered as the scope of the description as long as they are not contradictory.

The above-mentioned embodiments only express several embodiments of the application, and the description of them is more specific and detailed, but they cannot be understood as a restriction on the scope of the claims. It should be pointed out that a person of ordinary skill in the art can also make some modifications and improvements without departing from the ideas of the application, all of these belong to the scope of this application. Therefore, the scope of the patent application shall be subject to the attached claims.

What is claimed is:

1. A method for preparing a trench isolation structure, comprising:
opening a trench on a substrate, and filling a first dielectric layer of a preset thickness at the bottom of the trench;
forming a compensation film on the sidewalls of the trench above the first dielectric layer;
filling a second dielectric layer into the trench to form the trench isolation structure, with the compensation film be completely consumed after filling the second dielectric layer.

2. The method for preparing a trench isolation structure according to claim 1, wherein said filling the first dielectric layer with a preset depth at the bottom of the trench comprises:
depositing a first dielectric material to fill up the trench;
etching back the first dielectric material, and reserving the first dielectric material at the bottom of the trench, wherein the reserved first dielectric material forms the first dielectric layer.

3. The method for preparing a trench isolation structure according to claim 2, wherein the depth of the first dielectric material etched back within the trench ranges from 70 nm to 300 nm.

4. The method for preparing a trench isolation structure according to claim 1, wherein said forming the compensation film on the sidewalls of the trench above the first dielectric layer comprises:
depositing a compensation material to cover the sidewalls of the trench, the upper surface of the first dielectric layer and the upper surface of the substrate;
etching back the compensation material to remove the compensation material located on the upper surface of the first dielectric layer and the upper surface of the substrate, reserving the compensation material located at the sidewalls of the trench, wherein the reserved compensation material forms the compensation film.

5. The method for preparing a trench isolation structure according to claim 1, wherein the compensation film is a polysilicon layer.

6. The method for preparing a trench isolation structure according to claim 5, wherein the thickness of the polysilicon layer ranges from 5 Å to 50 Å.

7. The method for preparing a trench isolation structure according to claim 1, wherein after forming the compensation film on the sidewalls of the trench above the first dielectric layer and before filling the second dielectric layer into the trench to form the trench isolation structure, the method further comprises:
removing the first dielectric layer.

8. The method for preparing a trench isolation structure according to claim 1, wherein the processes used for filling the second dielectric layer within the trench include chemical vapor deposition, physical vapor deposition, atomic layer deposition or spin-coating insulating dielectric layer process.

9. The method for preparing a trench isolation structure according to claim 1, wherein the second dielectric layer comprises one or more of oxides, nitrides and nitrogen oxides.

10. A method for preparing a semiconductor device, comprising:
preparing a trench isolation structure on a substrate by the method for preparing a trench isolation structure according to claim 1 to define an active region; and
preparing a transistor structure in the active region to form the semiconductor device.

11. The method for preparing a semiconductor device according to claim 10, wherein the semiconductor device is a dynamic random access memory, and a gate of the transistor is prepared within the substrate to form a buried word line.

12. The method for preparing a semiconductor device according to claim 10, wherein said filling the first dielectric layer with a preset depth at the bottom of the trench comprises:
depositing a first dielectric material to fill up the trench; and
etching back the first dielectric material, and reserving the first dielectric material at the bottom of the trench, wherein the reserved first dielectric material forms the first dielectric layer.

13. The method for preparing a semiconductor device according to claim 12, wherein the depth of the first dielectric material etched back within the trench ranges from 70 nm to 300 nm.

14. The method for preparing a semiconductor device according to claim 10, wherein said forming the compensation film on the sidewalls of the trench above the first dielectric layer comprises:
depositing a compensation material to cover the sidewalls of the trench, the upper surface of the first dielectric layer and the upper surface of the substrate; and
etching back the compensation material to remove the compensation material located on the upper surface of the first dielectric layer and the upper surface of the substrate, reserving the compensation material located at the sidewalls of the trench, wherein the reserved compensation material forms the compensation film.

15. The method for preparing a semiconductor device according to claim 10, wherein the compensation film is a polysilicon layer.

16. The method for preparing a semiconductor device according to claim 15, wherein the thickness of the polysilicon layer ranges from 5 Å to 50 Å.

17. The method for preparing a semiconductor device according to claim 10, wherein after forming the compensation film on the sidewalls of the trench above the first dielectric layer and before filling the second dielectric layer into the trench to form the trench isolation structure, the method further comprises:
removing the first dielectric layer.

18. The method for preparing a semiconductor device according to claim 10, wherein the processes used for filling the second dielectric layer within the trench include chemical vapor deposition, physical vapor deposition, atomic layer deposition or spin-coating insulating dielectric layer process.

19. The method for preparing a semiconductor device according to claim 10, wherein the second dielectric layer comprises one or more of oxides, nitrides and nitrogen oxides.
